(19) United States
(12) Patent Application Publication
(10) Pub. No.: US 2026/0251711 A1
(43) Pub. Date: Aug. 27, 2026

(54) CLOCKLESS PULSE DETECTION CIRCUIT

(71) Applicant: STMicroelectronics International N.V., Geneva (CH)

(72) Inventors: Michele Giorgio, Milan (IT); Stefano Colli, Pavia (IT); Matteo Alessio Traldi, Milano (IT); Paolo Pulici, Lainate (MI) (IT)

(21) Appl. No.: 19/061,299

(22) Filed: Feb. 24, 2025

(51) Int. Cl. G01R 31/3183; H03K 17/08; H03K 17/22; H03K 19/20

(52) U.S. Cl. CPC G01R 31/3183; H03K 17/08; H03K 17/22; H03K 19/20

(57) ABSTRACT

According to an embodiment, a fault detection circuit monitors differential input signals without requiring a clock reference. A detector and stretcher circuit receives the differential input signals and generates differential output signals with asymmetric rise and fall times using unbalanced current sources. A timer circuit monitors these output signals and generates a reset signal when both differential output signals are in a low state. The timer circuit includes a charging network and generates a fault signal when a time between reset signals exceeds a threshold.

### TECHNICAL FIELD

The present disclosure generally relates to electronic devices and, in particular embodiments, to a clockless pulse detection circuit.

### BACKGROUND

Hard disk drives (HDDs) store data by converting digital signals into magnetic patterns on rotating disks. Typically, a preamplifier interfaces between a System-on-chip (SoC) controller and magnetic write heads. The preamplifier can receive differential signals in the Emitter Coupled Logic (ECL) or Current-Mode Logic (CML) domains, which can operate with voltage swings around hundreds of millivolts and varying common mode levels.

Modern HDD write operations demand increasingly higher data rates, with signal frequencies ranging from hundreds of megahertz to several gigahertz. These high-speed signals require precise timing control and monitoring to maintain data integrity. The write signal path includes multiple stages from the SoC through the preamplifier and ultimately to the write heads, where the signals are converted into magnetic field changes on the disk surface. Each transition in the input signal represents encoded data that gets written as magnetic patterns.

The mixed-signal environment of HDD electronics presents unique challenges. The analog circuits handle sensitive high-frequency signals susceptible to noise and interference, while digital control logic manages system operation and monitoring functions. Process variations during manufacturing, supply voltage fluctuations, and temperature changes across operating conditions (collectively known as PVT variations) can significantly impact circuit timing and performance characteristics.

### SUMMARY

Technical advantages are generally achieved by embodiments of this disclosure, which describe a clockless pulse detection circuit.

A first aspect relates to a system, comprising a writer circuit configured to receive differential input signals from a System on Chip (SoC), and generate write currents through a magnetic recording head based on the differential input signals; and a fault detection circuit comprising a detector and stretcher circuit configured to monitor the differential input signals received by the writer circuit; and generate differential output signals having asymmetric rise and fall times, and a timer circuit coupled to the detector and stretcher circuit and configured to monitor the differential output signals; generate a reset signal in response to the differential output signals being in a low state; and generate a fault signal in response to a time between reset signals exceeding a threshold.

A second aspect relates to a circuit, comprising a detector and stretcher circuit configured to receive differential input signals, and generate differential output signals having asymmetric rise and fall times; and a timer circuit coupled to the detector and stretcher circuit and configured to monitor the differential output signals, generate a reset signal in response to the differential output signals being in a low state, and generate a fault signal in response to a time between reset signals exceeding a threshold.

A third aspect relates to a method, comprising receiving differential input signals; generating differential output signals having asymmetric rise and fall times based on the differential input signals; monitoring the differential output signals; generating a reset signal in response to the differential output signals being in a low state; and generating a fault signal in response to a time between reset signals exceeding a threshold.

Embodiments can be implemented in hardware, software, or any combination thereof.

### BRIEF DESCRIPTION OF THE DRAWINGS

For a more complete understanding of the present disclosure and the advantages thereof, reference is now made to the following descriptions taken in conjunction with the accompanying drawings, in which:

FIG. 1 is a writer circuit implemented in a hard disk drive (HDD) preamplifier system;

FIG. 2 show signal characteristics and fault conditions in the input signals to the writer circuit;

FIG. 3 is a block diagram of a fault detection circuit for monitoring differential input signals in the writer circuit;

FIG. 4 is a schematic of an embodiment detector and stretcher circuit;

FIG. 5 is a schematic of an embodiment timer circuit;

FIG. 6 is a schematic of an embodiment detector and stretcher circuit;

FIG. 7 is a block diagram of a pre-amplifier placed on the disk drive head stack assembly of a hard disk drive; and

FIG. 8 is a flowchart of an embodiment method to operate a fault detection circuit for monitoring differential input signals in the writer circuit.

### DETAILED DESCRIPTION OF ILLUSTRATIVE EMBODIMENTS

This disclosure provides many applicable inventive concepts that can be embodied in a wide variety of specific contexts. The particular embodiments are merely illustrative of specific configurations and do not limit the scope of the claimed embodiments. Features from different embodiments may be combined to form further embodiments unless noted otherwise. Various embodiments are illustrated in the accompanying drawing figures, where identical components and elements are identified by the same reference number, and repetitive descriptions are omitted for brevity.

Variations or modifications described in one of the embodiments may also apply to others. Further, various changes, substitutions, and alterations can be made herein without departing from the spirit and scope of this disclosure as defined by the appended claims.

While the inventive aspects are described primarily in the context of hard disk drive preamplifiers and write signal monitoring, it should also be appreciated that these inventive aspects may also apply to any radio frequency (RF) applications requiring pulse detection or applications where pulse durations higher than a threshold need to be detected. In particular, aspects of this disclosure may similarly apply to signal monitoring in high-speed data transmission systems, pulse width detection circuits, and frequency monitoring applications where external clock references are undesirable or impractical.

In embodiments, a pulse detection circuit provides clock-free monitoring of high-frequency differential signals by combining analog transition detection with charge-based timing. The circuit can include a transition detector that receives differential inputs in, for example, Emitter-Coupled Logic (ECL) or Current-Mode Logic (CML) formats and generates corresponding differential outputs with controlled timing asymmetry. Through unbalanced current sources and parasitic capacitances, the transition detector can produce output signals with fall times shorter than rise times, creating distinct overlapping low-voltage periods whenever input transitions occur. In embodiments, the transition detector can accommodate ECL and CML signaling schemes, which operate with similar voltage swings of several hundred millivolts but different common mode levels, allowing flexibility in interface requirements while maintaining similar detection principles.

A Complementary Metal Oxide Semiconductor (CMOS) logic circuit can monitor these asymmetric differential outputs and generate reset pulses during the overlapping low periods. The logic implementation remains simple, requiring only basic gates to detect when both outputs are simultaneously in their low states. The reset pulse width depends on the transition detector's timing characteristics, configured to accommodate the maximum input frequencies while ensuring reliable capacitor discharge in the timer circuit.

The timer circuit can employ continuous charge accumulation between reset pulses using either current source or resistive charging networks. When reset pulses occur frequently due to normal input transitions, the accumulated charge remains below a fault threshold. However, if input transitions cease longer than the specified time window, the charge builds up beyond the threshold and triggers a fault output. The charging behavior can be linear using current sources or exponential using resistors, with the time constant selected based on application requirements.

In embodiments, the transition detector architecture centers around a bipolar differential pair with intentionally mismatched current sources. A large discharge current coupled with parasitic capacitance creates rapid output transitions to the low state, while smaller charging currents produce slower rises back to the high state. Clamping circuits can be used to control the minimum output voltage to ensure proper CMOS logic interfacing. The complete analog signal path maintains high bandwidth while minimizing circuit complexity.

To account for Process, Voltage, and Temperature (PVT) variations, the circuit can incorporate trimming networks that adjust critical parameters like capacitance values or charging currents. These trimming capabilities ensure consistent timing across different operating conditions without requiring complex calibration schemes. The fully analog implementation avoids noise and interference issues plaguing clock-based solutions while enabling reliable operation at higher frequencies.

The pulse detection approach offers advantages over conventional implementations that rely on clock references and digital counters. The circuit reduces power consumption and potential noise injection into sensitive analog signal paths by eliminating the clock. The analog timing mechanism removes fundamental frequency detection limitations imposed by clock period uncertainties in synchronous designs. The streamlined architecture enables efficient integration in mixed-signal environments while maintaining high detection accuracy across wide frequency ranges. These and additional details are discussed below.

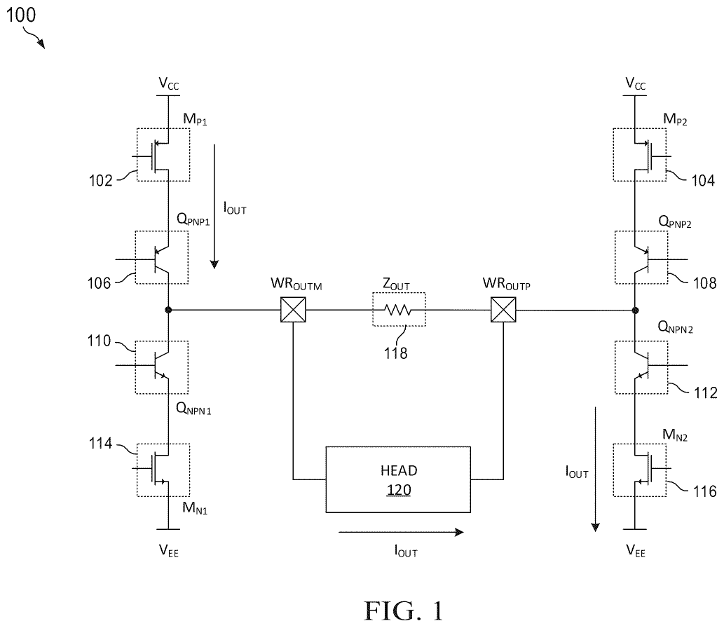

FIG. 1 illustrates a writer circuit 100 implemented in a hard disk drive (HDD) preamplifier system. The writer circuit 100 features a full-bridge configuration with first and second branches that deliver bidirectional write currents through a magnetic recording head 120 (for example, consisting of a resistor and a coil). Each branch incorporates complementary bipolar and MOS transistors arranged in an H-bridge configuration, allowing for precise current control and fast switching.

The first branch includes a first p-channel transistor (M_{P1}) 102, a first PNP transistor (Q_{PNP1}) 106, a first NPN transistor (Q_{NPN1}) 110, and a first n-channel transistor (M_{N1}) 114. The second branch includes a second p-channel transistor (M_{P2}) 104, a second PNP transistor (Q_{PNP2}) 108, a second NPN transistor (Q_{NPN2}) 112, and a second n-channel transistor (M_{N2}) 116.

The writer circuit 100 combines CMOS drivers with an NPN-PNP H-bridge configuration to provide precise current control. In the first branch, the first PNP transistor (Q_{PNP1}) 106 couples between the first p-channel transistor (M_{P1}) 102 and the first NPN transistor (Q_{NPN1}) 110, which in turn couples to the first n-channel transistor (M_{N1}) 114. Similarly, in the second branch, the second PNP transistor (Q_{PNP2}) 108 couples between the second p-channel transistor (MP2) 104 and the second NPN transistor (Q_{NPN2}) 112, which couples to the second n-channel transistor (MN2) 116.

The bridge circuit provides write output current (I_{OUT}) through an impedance matching network (Z_{OUT}) 118 to the magnetic recording head 120. The first node (WR_{OUTM}) is a common node between the first PNP transistor (Q_{PNP1}) 106, the first NPN transistor (Q_{NPN1}) 110, and the impedance matching network (Z_{OUT}) 118. The second node (WR_{OUTP}) is a common node between the second PNP transistor (Q_{PNP2}) 108, the second NPN transistor (Q_{NPN2}) 112, and the impedance matching network (Z_{OUT}) 118.

The CMOS drivers control the overall current levels, while the bipolar transistors enable rapid switching between diagonal pairs. When the transistors in one diagonal pair activate, current flows through the magnetic recording head 120 in one direction, creating a magnetic field of a specific polarity. Conversely, when the transistors in the opposite diagonal pair activate, current flows in the reverse direction, producing a magnetic field of the opposite polarity. These alternating magnetic fields generate different magnetic orientations on the storage medium, thus encoding binary data.

The impedance matching network (Z_{OUT}) 118 adjusts the characteristic impedance of the transmission line connecting the bridge circuit to the magnetic recording head 120. In various embodiments, the impedance matching network (Z_{OUT}) 118 can be set to different levels, such as 30, 35, 40, and 45 ohms, depending on the write output current (I_{OUT}) requirements. During normal operation, the write output current (I_{OUT}) through the magnetic recording head 120 can vary from a few milliamperes to 105 mA.

The impedance matching considerations are similar to Radio Frequency (RF) matching techniques but require broadband matching across a wide frequency range from Direct Current (DC) to several gigahertz. Unlike narrow-band RF applications, the writer circuit operates over a complete bandwidth to support fast current transitions required for high-speed data writing. Parasitic capacitances can exist at the interface between the bridge circuit and the transmission line.

The writer circuit 100 receives differential input signals from the System on Chip (SoC). These differential signals operate with several hundred millivolts voltage swings and defined common mode levels. The signals carry the data patterns that control the switching of current direction through the magnetic recording head 120 via the H-bridge configuration.

The high-frequency operation of these differential signals, ranging from hundreds of megahertz to several gigahertz, demands careful signal integrity management throughout the writer circuit 100. The differential signaling scheme helps maintain noise immunity, while the impedance matching network (Z_{OUT}) 118 helps preserve signal quality through the transmission path. The small voltage swings characteristic of ECL signaling, combined with the high operating frequencies, make the signals particularly sensitive to noise and interference.

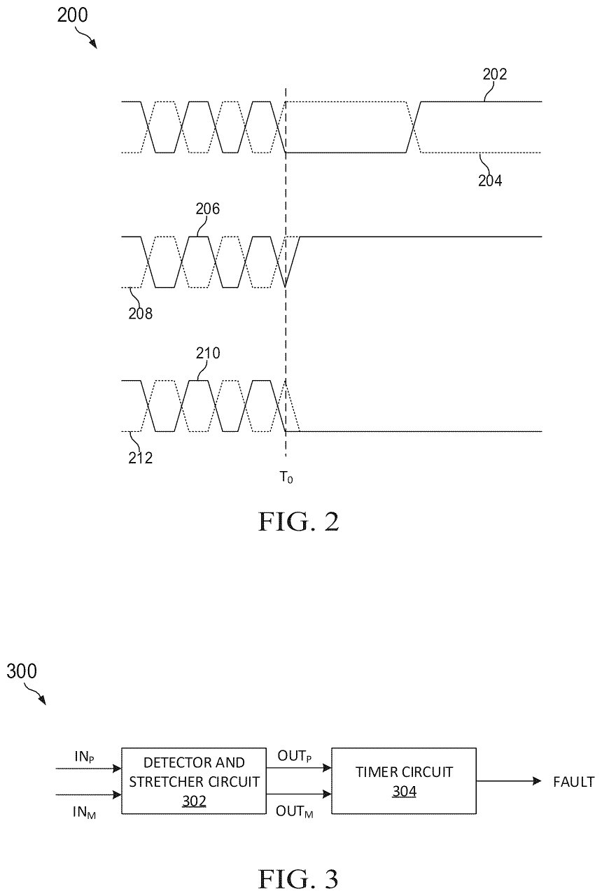

FIG. 2 illustrates signal characteristics and fault conditions in the input signals to the writer circuit 100. The signals shown represent differential inputs using Emitter Coupled Logic (ECL) signaling, which operates with typical voltage swings of several hundred millivolts and defined common mode levels. These high-speed differential signals from the System on Chip (SoC) carry the data patterns to be written to the magnetic storage medium. In embodiments, the differential signals are in the Emitter Coupled Logic (ECL) or Current-Mode Logic (CML) domains.

Under normal operation before time T₀, the differential signal pairs maintain regular transitions at frequencies up to several gigahertz. The small voltage swings and differential nature of ECL signaling enable reliable high-speed data transmission while maintaining signal integrity. Each differential pair includes complementary signals that transition between logic states to encode the write data.

FIG. 2 demonstrates three possible fault conditions occurring at time T₀. The first differential pair includes signal 202 and signal 204, showing reduced frequency operation where transitions continue but become less frequent after time T₀. The second differential pair includes signal 206 and signal 208, illustrating a fault condition where the signal is removed at time T₀, with both signals stopping their transitions. Similarly, the third differential pair includes signal 210 and signal 212, showing another example of signal removal at time T₀, where both signals cease transitioning simultaneously.

Detecting these fault conditions presents several challenges in the high-speed data transmission environment. Without an external clock reference, the monitoring circuit can rely only on the input signal transitions themselves. Additionally, process, voltage, and temperature (PVT) variations can affect the detection accuracy, particularly when determining the minimum detectable frequency. The detection circuit should maintain tight tolerance across these variations to ensure reliable fault reporting while operating in the sensitive analog environment of the writer circuit 100.

When these fault conditions occur, the data writing operation may be compromised. Therefore, rapidly detecting reduced frequency or missing transitions becomes advantageous for maintaining proper system operation. The monitoring circuit should detect these conditions and generate appropriate fault signals while avoiding the introduction of noise or interference that could further degrade the signal integrity.

Conventional approaches to detecting differential signal frequency drops typically employ digital counters with clock-based timing references. For example, a pulse detector can generate an internal clock signal on the chip. The counter resets each time a differential input signal transition occurs, tracking the time between transitions. The circuit generates a fault signal when the counter reaches a predetermined value, indicating excessive time has passed without transitions in the differential signals.

The counter-based approach compares the time between signal transitions against a clock-derived threshold. This threshold corresponds to the maximum allowable period between transitions, effectively monitoring the minimum acceptable frequency of the differential input signals. The digital counter increments with each clock cycle and resets upon detecting transitions in the signal pair.

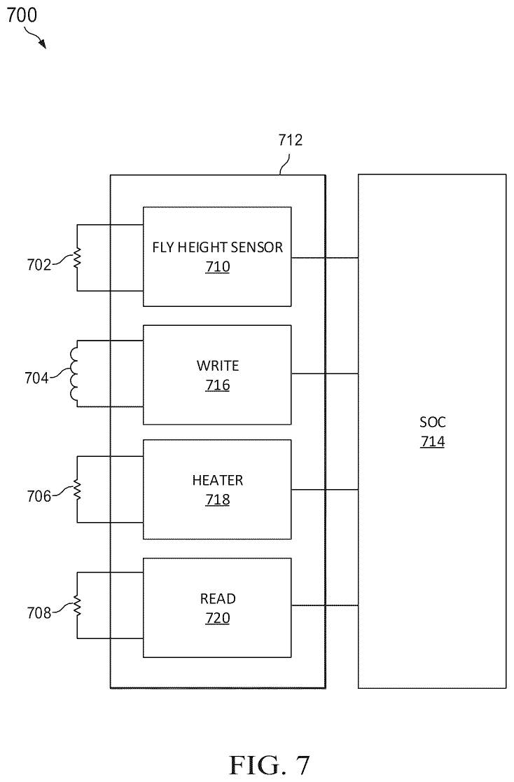

However, the clock-based implementation can introduce several drawbacks. An internal clock signal can represent an unwanted noise and interference source that degrades the performance of other circuitries that instead handle small analog signals and are sensitive to noise. For example, the fly height sensor 710 and the read circuit 720 are examples of sensitive circuits in the pre-amplifier 712 of FIG. 7.

Another limitation arises from the asynchronous relationship between the clock and input signals. Since the differential transitions can occur at any time relative to the clock edges, an inherent uncertainty of one clock period can affect the measurement accuracy. This uncertainty limits the maximum detectable frequency and reduces the precision of the frequency monitoring, which is particularly critical for high-speed signaling.

The digital counter implementation also increases power consumption due to the continuous clock generation and counter operation. The additional power requirements and circuit complexity can impact overall system efficiency. This becomes particularly important when monitoring multiple differential signal pairs in applications where power constraints are important considerations.

FIG. 3 illustrates a block diagram of a fault detection circuit 300 for monitoring differential input signals in the writer circuit 100. The fault detection circuit 300 implements an analog approach to detect reduced frequency or missing transitions without requiring a clock reference, avoiding the drawbacks of conventional clock-based monitoring solutions. In embodiments, the differential signals are in the Emitter Coupled Logic (ECL) or Current-Mode Logic (CML) domains.

The fault detection circuit 300 includes a detector and stretcher circuit 302 coupled to a timer circuit 304. The detector and stretcher circuit 302 receives differential input signals (IN_{P} and IN_{M}), which are the differential signals from the System on Chip (SoC) operating with hundreds of millivolt swings at frequencies up to several gigahertz. These input signals carry the data patterns that control the writer circuit 100, making their integrity and proper frequency monitoring critical for system operation.

The detector and stretcher circuit 302 generates differential output signals (OUT_{P} and OUT_{M}) in response to transitions detected in the differential input signals (IN_{P} and IN_{M}). The circuit exploits timing asymmetry to create overlapping low-state periods in the positive differential output signal (OUT_{P}) and the negative differential output signal (OUT_{M}). When a transition occurs in the input signals, the positive differential output signal (OUT_{P}) and the negative differential output signal (OUT_{M}) are driven to a low state for a predetermined time window. This stretched pulse width ensures reliable reset operation of the timer circuit 304.

The asymmetric timing is achieved by setting the fall time of the output signals to be substantially shorter than their rise time. This characteristic ensures that the positive differential output signal (OUT_{P}) and the negative differential output signal (OUT_{M}) can be simultaneously low during input transitions, even though the differential input signals (IN_{P} and IN_{M}) are never simultaneously low due to their complementary nature. The duration of this overlapping low period is controlled to provide reliable timer reset operation while maintaining compatibility with the maximum input frequency.

The timer circuit 304 receives the differential output signals (OUT_{P} and OUT_{M}) from the detector and stretcher circuit 302. During normal operation with regular input transitions, the overlapping low periods in the positive differential output signal (OUT_{P}) and the negative differential output signal (OUT_{M}) repeatedly reset the timer circuit 304 before it reaches its threshold. The timer circuit 304 accumulates charge after each reset, but under normal conditions, another reset occurs before the threshold is reached.

However, if the input signal transitions become too infrequent or stop entirely, as illustrated by the fault conditions in FIG. 2, the timer circuit 304 continues accumulating charge without being reset. When the accumulated charge reaches a predetermined threshold, the timer circuit 304 triggers a FAULT output signal, indicating that the input signal frequency has dropped below an acceptable level or the signals have stopped transitioning.

By implementing a fully analog approach, the fault detection circuit 300 avoids introducing clock-related noise while maintaining high sensitivity to input signal transitions. The circuit can operate with input frequencies ranging from hundreds of megahertz to several gigahertz, accommodating the full range of normal operating conditions for the writer circuit 100.

In embodiments of the disclosure, the fault detection circuit 300 can operate with input data rates up to several gigabits per second (Gbps) (e.g., 7 Gbps), whereas the detector and stretcher circuit 302 reliably detects single pulses as narrow as hundred(s) of picoseconds (e.g., 140 ps). This high-speed capability ensures proper monitoring of the fastest expected data rates in the writer circuit 100 while maintaining accurate fault detection across all operating conditions.

The fault detection circuit 300 can maintain reliable operation across PVT variations by configuring the timer circuit 304 parameters. The analog implementation allows for precise control of timing parameters while minimizing additional power consumption compared to clock-based solutions, and the absence of the clock avoids any unwanted interference with other sensitive circuitries.

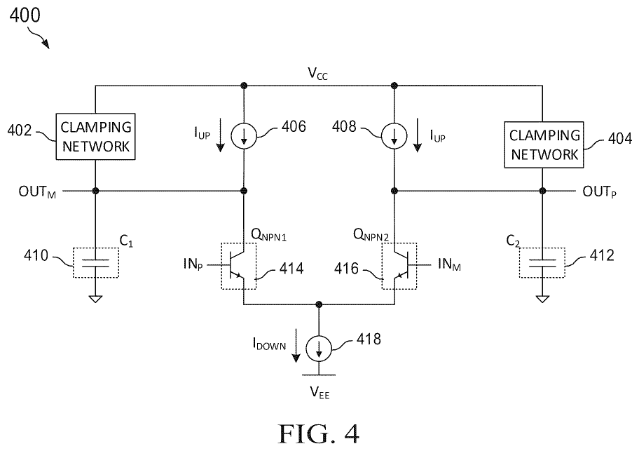

FIG. 4 illustrates a schematic of an embodiment detector and stretcher circuit 400, which can be implemented as the detector and stretcher circuit 302 of FIG. 3. The detector and stretcher circuit 400 includes a first clamping network 402, a second clamping network 404, a first current source 406, a second current source 408, a first capacitor (C₁) 410, a second capacitor (C₂) 412, a first NPN transistor (Q_{NPN1}) 414, a second NPN transistor (Q_{NPN2}) 416, and a third current source 418, which may (or may not) be arranged as shown. The detector and stretcher circuit 400 may include additional components not shown.

The detector and stretcher circuit 400 receives the positive differential input signal (IN_{P}) and the negative differential input signal (IN_{M}) at the base terminals of the first NPN transistor (Q_{NPN1}) 414 and the second NPN transistor (Q_{NPN2}) 416, respectively. These transistors form a differential pair that switches the pull-down current (I_{DOWN}) generated by the third current source 418 between their collector paths based on the input signal states. The collector terminals of the first NPN transistor (Q_{NPN1}) 414 and the second NPN transistor (Q_{NPN2}) 416 generate the negative differential output signal (OUT_{M}) and the positive differential output signal (OUT_{P}), respectively.

The first current source 406 and the second current source 408 each generate a pull-up current (I_{UP}) that tends to pull their respective output nodes toward the supply voltage (V_{CC}) with a slope of the pull-up current (I_{UP}) divided by the respective capacitance. The third current source 418 generates a pull-down current (I_{DOWN}) substantially larger than the pull-up current (I_{UP}) (e.g., 10 to 100 times larger), creating asymmetrical timing characteristics in the output signals.

When the pull-down current (I_{DOWN}) flows through either transistor's collector path, it pulls the corresponding output node toward the supply voltage (V_{EE}). The first clamping network 402 and the second clamping network 404 are coupled between the collector terminals of the first NPN transistor (Q_{NPN1}) 414 and the second NPN transistor (Q_{NPN2}) 416, and the supply voltage (V_{CC}). This configuration establishes appropriate logic levels for driving subsequent Complementary Metal Oxide Semiconductor (CMOS) circuits operating between the supply voltage (V_{CC}) and the supply voltage (V_{EE}). The first clamping network 402 and the second clamping network 404 prevent the output nodes from being pulled completely to the supply voltage (V_{EE}), maintaining a minimum voltage level that ensures proper interfacing with the subsequent CMOS stages.

When the positive differential input signal (IN_{P}) is high relative to the negative differential input signal (IN_{M}), the first NPN transistor (Q_{NPN1}) 414 conducts most of the pull-down current (I_{DOWN}), quickly pulling the negative differential output signal (OUT_{M}) low. In contrast, the positive differential output signal (OUT_{P}) rises slowly due to the pull-up current (I_{UP}).

Conversely, when the positive differential input signal (IN_{P}) is low relative to the negative differential input signal (IN_{M}), the second NPN transistor (Q_{NPN2}) 416 conducts most of the pull-down current (I_{DOWN}), quickly pulling the positive differential output signal (OUT_{P}) low. In contrast, the negative differential output signal (OUT_{M}) rises slowly. The asymmetrical current relationship makes output fall times much shorter than output rise times.

This timing asymmetry enables the negative differential output signal (OUT_{M}) and the positive differential output signal (OUT_{P}) to be simultaneously in their low states for a controlled duration whenever an input transition occurs, even though the positive differential input signal (IN_{P}) and the negative differential input signal (IN_{M}) are never simultaneously low due to their complementary nature. The duration of the overlapping low states depends on the ratio of the down current (I_{DOWN}) to the pull-up current (I_{UP}) and the values of the first capacitor (C₁) 410 and the second capacitor (C₂) 412.

The first capacitor (C₁) 410 and the second capacitor (C₂) 412 work with the current sources to establish the timing characteristics. In embodiments, the parasitic capacitances at the output nodes may be sufficient to implement the first capacitor (C₁) 410 and the second capacitor (C₂) 412, eliminating the need for additional capacitors while reducing power consumption since the pull-down current (I_{DOWN}) can be minimized.

The timing parameters are chosen to ensure reliable detection of input transitions as fast as hundred(s) of picoseconds (e.g., 140 ps) while generating output pulses wide enough to reset the timer circuit 304 properly. The fall time, determined by the pull-down current (I_{DOWN}) divided by the capacitance, is much shorter than the minimum input pulse width. Simultaneously, the pull-up current (I_{UP}) divided by the capacitance sets a rise time that creates a sufficient overlap of low states at the negative differential output signal (OUT_{M}) and the positive differential output signal (OUT_{P}) to ensure a reliable timer reset.

Through this mechanism, the detector and stretcher circuit 400 functions as a pulse stretcher, creating overlapping low periods in both outputs whenever an input transition occurs. The stretched pulses provide robust reset signals to the timer circuit 304 while maintaining operation at input frequencies up to several gigabits per second. The fully analog implementation avoids introducing clock-related noise while providing precise control of timing parameters.

Although the detector and stretcher circuit 400 is shown implemented with NPN transistors, it should be appreciated that different arrangements and components may be contemplated in other embodiments. For example, the detector and stretcher circuit 400 may be implemented using PNP transistors with appropriate voltage polarity adjustments or a combination of different transistor types. The selection of transistor types and corresponding circuit arrangements may be based on process technology, voltage requirements, or performance specifications while maintaining the same functional principles of generating asymmetric timing characteristics in the differential output signals.

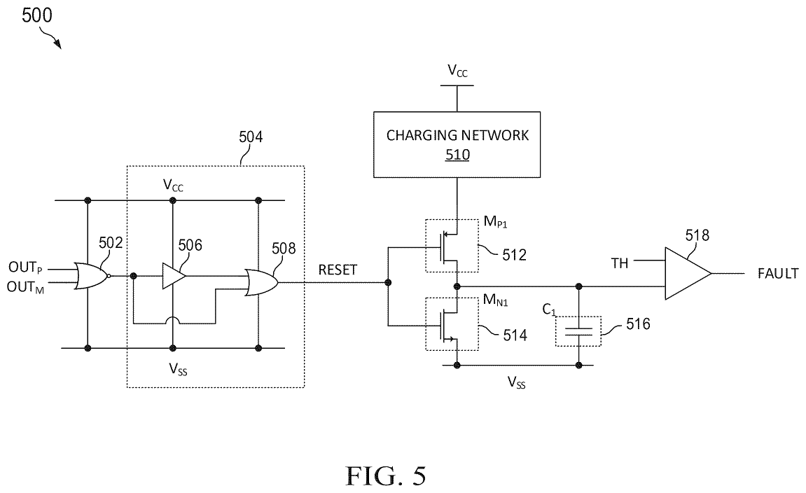

FIG. 5 illustrates a schematic of an embodiment timer circuit 500, which can be implemented as the timer circuit 304 of FIG. 3. The timer circuit 500 includes a NOR gate 502, a Complementary Metal Oxide Semiconductor (CMOS) pulse stretcher 504, a charging network 510, a first p-channel transistor (M_{P1}) 512, a first n-channel transistor (M_{N1}) 514, a first capacitor (C₁) 516, and a comparator 518, which may (or may not) be arranged as shown. The CMOS pulse stretcher 504 includes a buffer circuit 506 and an OR gate 508. Timer circuit 500 may include additional components not shown.

The NOR gate 502 receives the negative differential output signal (OUT_{M}) and the positive differential output signal (OUT_{P}) from the detector and stretcher circuit 400. When the negative differential output signal (OUT_{M}) and the positive differential output signal (OUT_{P}) are low, which occurs during input signal transitions due to the asymmetric timing characteristics described in FIG. 4, the NOR gate 502 output goes high. The CMOS pulse stretcher 504 extends this high period through the buffer circuit 506 and the OR gate 508 to generate the RESET signal.

The buffer circuit 506 delays (i.e., buffers) the output of the NOR gate 502, and the OR gate 508 combines this buffered signal with the original NOR gate 502 output. This arrangement in the CMOS pulse stretcher 504 creates a RESET pulse wider than the overlapping low period of the negative differential output signal (OUT_{M}) and the positive differential output signal (OUT_{P}), ensuring reliable capacitor discharge.

The RESET signal controls the first p-channel transistor (M_{P1}) 512 and the first n-channel transistor (M_{N1}) 514, which form a discharge path for the first capacitor (C₁) 516. The source terminal of the first n-channel transistor (M_{N1}) 514 is coupled to the supply voltage (V_{SS}), which is the minimum voltage reachable at the output of the detector and stretcher circuit 400 due to the clamping networks. The drain terminals of the transistors are coupled together at a common node with the first capacitor (C₁) 516, which couples between this common node and the supply voltage (V_{SS}). When the RESET signal is at a logic high, the n-channel transistor (M_{N1}) 514 conducts and discharges the first capacitor (C₁) 516 to its initial state. The discharge occurs each time the negative differential output signal (OUT_{M}) and the positive differential output signal (OUT_{P}) are simultaneously low, corresponding to input signal transitions.

The charging network 510 couples between the supply voltage (V_{CC}) and the source terminal of the first p-channel transistor (M_{P1}) 512. In embodiments, the charging network 510 is implemented as a current source that generates a current (I). In these embodiments, the voltage across the first capacitor (C₁) 516 is linearly increasing with a slope equal to the current (I) divided by the capacitance of the first capacitor (C₁) 516. In embodiments, the charging network 510 is implemented as a resistor. In these embodiments, the voltage across the first capacitor (C₁) 516 is charged with an exponential charging characteristic with a time constant equal to the resistance of the resistor multiplied by the capacitance of the first capacitor (C₁) 516.

When the RESET signal is at a logic low, indicating no recent transitions in the input signals, the charging network 510 begins charging the first capacitor (C₁) 516. The charging continues until either another RESET pulse occurs due to new input transitions or until the voltage across the first capacitor (C₁) 516 reaches the threshold (TH) at the input of the comparator 518.

The comparator 518, which can be implemented as an inventor or a comparator circuit (as shown), monitors the voltage across the first capacitor (C₁) 516. In embodiments where an inverter is used, the inverter's switching threshold serves as the reference point, eliminating the need for an external threshold voltage (TH). In other embodiments, a comparator circuit can be used with an external threshold voltage (TH) provided at its reference input. During normal operation with regular input transitions, the periodic RESET pulses prevent the capacitor voltage from reaching the inverter's switching threshold voltage or the external threshold voltage (TH). However, if the negative differential output signal (OUT_{M}) and the positive differential output signal (OUT_{P}) stop transitioning or become too infrequent, as shown in the fault conditions of FIG. 2, the capacitor voltage rises until triggering the FAULT signal.

The timing characteristics of the timer circuit 500 are coordinated with the detector and stretcher circuit 400 to ensure reliable fault detection. The RESET pulse width, determined by the detector and stretcher circuit 400 and the CMOS pulse stretcher 504, should be sufficient to fully discharge the first capacitor (C₁) 516. Meanwhile, the charging rate set by the charging network 510 determines the maximum allowable time between input transitions before a fault is declared.

In embodiments, the system initiates protective measures by stopping ongoing operations in response to a FAULT signal being declared. This immediate response can be advantageous since a missing or low-frequency input signal indicates a potential system issue that could compromise data integrity. The fault detection mechanism can be a safeguard, particularly in disk write operations.

In normal disk write operations, the system continuously writes alternating patterns of zeros and ones to the disk. The probability of writing exclusively zeros or exclusively ones for an extended period (such as hundred(s) of nanoseconds) is extremely low during proper operation. Therefore, when the input signal frequency drops below expected levels, it signals an abnormal condition that may stem from various sources (e.g., the System-on-Chip (SoC), the interconnections between the SoC and preamplifier, or the preamplifier itself). The FAULT signal can alert the system to these potential issues, enabling diagnostic measures and preventing potentially corrupted write operations. This early warning system can help maintain data integrity while providing diagnostic information about the source of the malfunction.

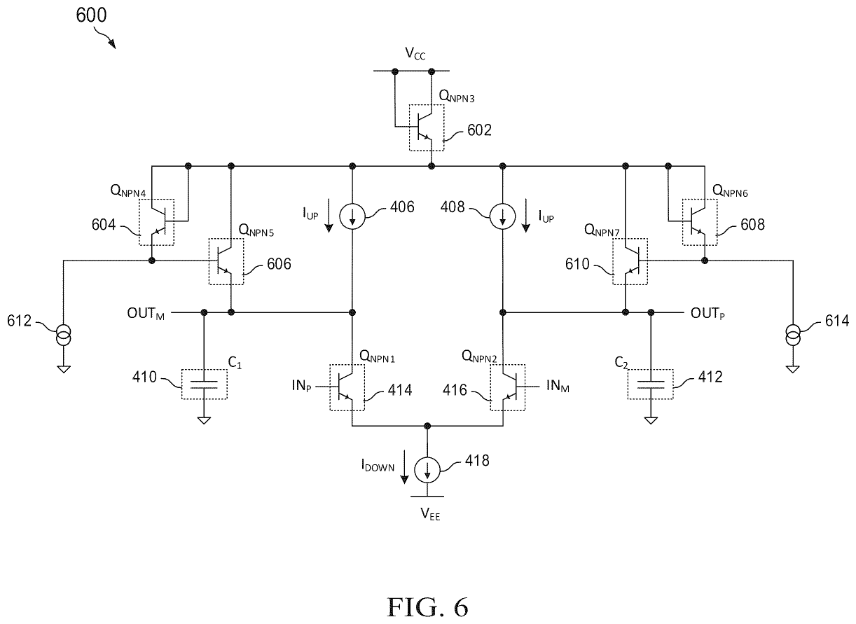

FIG. 6 illustrates a schematic of an embodiment detector and stretcher circuit 600, which can be implemented as the detector and stretcher circuit 302 of FIG. 3. The detector and stretcher circuit 600 expands upon the detector and stretcher circuit 400 of FIG. 4 by implementing an example of an implementation of clamping networks using NPN transistors in place of the first clamping network 402 and the second clamping network 404.

The detector and stretcher circuit 600 includes a third NPN transistor (Q_{NPN3}) 602 coupled between the supply voltage (V_{CC}) and a common node. The first clamping network 402 includes a fourth NPN transistor (Q_{NPN4}) 604, a fifth NPN transistor (Q_{NPN5}) 606, a current sink 612, and shares the third NPN transistor (Q_{NPN3}) 602 with the second clamping network 404. The second clamping network includes a sixth NPN transistor (Q_{NPN6}) 608, a seventh NPN transistor (Q_{NPN7}) 610, a second current sink 614, and shares the third NPN transistor (Q_{NPN3}) 602 with the first clamping network 402.

The third NPN transistor (Q_{NPN3}) 602, the fourth NPN transistor (Q_{NPN4}) 604, and the sixth NPN transistor (Q_{NPN6}) 608 are arranged as a diode-connected transistor where their base terminal is coupled to their collector terminals.

The detector and stretcher circuit 600 maintains the core functionality described in FIG. 4, including the first current source 406 and second current source 408 generating pull-up currents (I_{UP}), the third current source 418 generating the pull-down current (I_{DOWN}), the first capacitor (C₁) 410, and the second capacitor (C₂) 412. The first NPN transistor (Q_{NPN1}) 414 and the second NPN transistor (Q_{NPN2}) 416 form the differential pair receiving the positive differential input signal (IN_{P}) and the negative differential input signal (IN_{M}), respectively.

The first clamping network clamps the negative differential output signal (OUT_{M}), while the second clamping network clamps the positive differential output signal (OUT_{P}). The clamping networks limit the minimum voltage of their respective output nodes to a level that depends on the low voltage rail requirement of the subsequent logic circuits. In the illustrated embodiment, this level is approximately three base-emitter voltage drops (3×V_{BE}) below the supply voltage (V_{CC}), establishing appropriate logic levels for driving subsequent Complementary Metal Oxide Semiconductor (CMOS) circuits. The number of base-emitter voltage drops may vary in different embodiments of the specific requirements of the subsequent logic stages and the overall system architecture.

The asymmetric timing characteristics described in FIG. 4 are maintained, where the pull-down current (I_{DOWN}) is substantially larger than the pull-up current (I_{UP}), creating output fall times that are shorter than output rise times. This timing asymmetry enables the generation of overlapping low periods in the negative differential output signal (OUT_{M}) and the positive differential output signal (OUT_{P}) whenever an input transition occurs.

Although the detector and stretcher circuit 600 is shown implemented with NPN transistors in the clamping networks and differential pair, it should be appreciated that different arrangements and components may be contemplated in other embodiments. For example, the detector and stretcher circuit 600 may be implemented using PNP transistors with appropriate voltage polarity adjustments and complementary biasing. In such implementations, the clamping networks can be redesigned with PNP transistors, maintaining similar functionality but with inverted voltage relationships. The selection of transistor types and corresponding circuit arrangements may be based on process technology, voltage requirements, and performance specifications while maintaining the same functional principles of signal detection and pulse stretching.

FIG. 7 illustrates a block diagram of a pre-amplifier 712 that is placed on the disk drive head stack assembly of a hard disk drive. In embodiments, the writer circuit 100 is implemented as the write circuit 716 of the pre-amplifier 712.

The disk drive head stack assembly slides over the disk. The pre-amplifier 712 includes a fly height sensor 710. In embodiments, the fly height sensor 710 includes a biasing circuit and an amplifier (not shown). The fly height sensor 710 is coupled to a resistive sensor 702. The resistive sensor 702 monitors the fly height between the disk drive head and the disk itself.

A write coil 704 is coupled to the write circuit 716 (for writing to the disk), a heater resistor 706 is coupled to the heater circuit 718 (for controlling the fly height spacing), and a read resistor 708 is coupled to the read circuit 720 (for reading from the disk). The fly height sensor 710, write circuit 716, heater circuit 718, and read circuit 720 are coupled to a system-on-chip (SoC) 714 for processing.

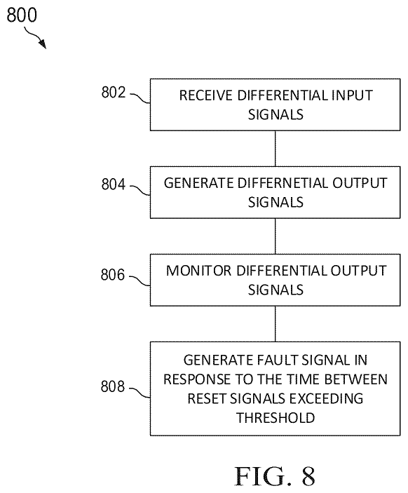

FIG. 8 illustrates a flowchart of an embodiment method 800 to operate a fault detection circuit for monitoring differential input signals in the writer circuit 100. It is noted that all steps outlined in the method are not necessarily required and can be optional. Further, changes to the arrangement of the steps, removal of one or more steps and path connections, and addition of steps and path connections are similarly contemplated. In embodiments, the differential signals are in the Emitter Coupled Logic (ECL) or Current-Mode Logic (CML) domains.

At step 802, the detector and stretcher circuit 302 receives differential input signals from the System on Chip (SoC). These differential signals operate with voltage swings of several hundred millivolts and defined common mode levels at frequencies up to several gigabits per second, where single pulses can be as narrow as hundred(s) of picoseconds. The differential signals encode data patterns that control the writer circuit 100, with their transitions representing data to be written to the magnetic storage medium.

In some embodiments, as shown in FIGS. 4 and 6, the detector and stretcher circuit 302 is implemented with a differential pair of NPN transistors, where the first NPN transistor (Q_{NPN1}) 414 and the second NPN transistor (Q_{NPN2}) 416 receive the positive differential input signal (IN_{P}) and the negative differential input signal (IN_{M}) at their base terminals.

At step 804, the detector and stretcher circuit 302 generates differential output signals with asymmetric timing characteristics. This asymmetry creates overlapping low-state periods in the output signals whenever an input transition occurs, while maintaining appropriate logic levels for driving subsequent circuits.

In some embodiments, as detailed in FIGS. 4 and 6, this asymmetry is achieved using unbalanced current sources where a pull-down current (I_{DOWN}) generated by the third current source 418 is 10 to 100 times larger than pull-up currents (I_{UP}) generated by the first current source 406 and second current source 408. In embodiments, the clamping networks limit the minimum voltage of the output nodes to approximately three base-emitter voltage drops below the supply voltage (V_{CC}).

At step 806, the timer circuit 304 monitors the differential output signals and generates reset pulses when both outputs are simultaneously low, indicating input transitions. These reset pulses control the discharge of a timing element within the timer circuit 304.

In some embodiments, as shown in FIG. 5, this is implemented using a NOR gate 502 that monitors the positive differential output signal (OUT_{P}) and negative differential output signal (OUT_{M}). A CMOS pulse stretcher 504, comprising a buffer circuit 506 and OR gate 508, extends the reset period to ensure complete discharge of a first capacitor (C₁) 516 through a first n-channel transistor (M_{N1}) 514.

At step 808, the timer circuit 304 generates a fault signal if the time between reset pulses exceeds a predetermined threshold. During normal operation, regular input transitions prevent the timing element from reaching its threshold. However, if transitions become too infrequent or stop entirely, as shown in the fault conditions of FIG. 2, the timing element reaches its threshold and triggers the fault signal.

In some embodiments, as detailed in FIG. 5, this is implemented using a charging network 510 that charges the first capacitor (C₁) 516 either linearly with a current source or exponentially with a resistor. A comparator 518 monitors the capacitor voltage against a threshold voltage (TH) and generates the FAULT signal when the threshold is exceeded.

A first aspect relates to a system, comprising a writer circuit configured to receive differential input signals from a System on Chip (SoC), and generate write currents through a magnetic recording head based on the differential input signals; and a fault detection circuit comprising a detector and stretcher circuit configured to monitor the differential input signals received by the writer circuit; and generate differential output signals having asymmetric rise and fall times, and a timer circuit coupled to the detector and stretcher circuit and configured to monitor the differential output signals; generate a reset signal in response to the differential output signals being in a low state; and generate a fault signal in response to a time between reset signals exceeding a threshold.

In a first implementation form of the system, according to the first aspect as such, the detector and stretcher circuit comprises a differential pair of transistors having base terminals configured to receive the differential input signals; a first current source and a second current source configured to generate pull-up currents; a third current source configured to generate a pull-down current; a first clamping network and a second clamping network coupled to collector terminals of the differential pair of transistors; and a first capacitor and a second capacitor coupled between the collector terminals and ground.

In a second implementation form of the system, according to the first aspect as such or any preceding implementation form of the first aspect, the first clamping network and the second clamping network are configured to limit a minimum voltage at the collector terminals of the differential pair of transistors to approximately N number of base-emitter voltage drops below the supply voltage, where N is an integer greater than two corresponding to the low voltage rail requirement of subsequent logic circuits in the system.

In a third implementation form of the system, according to the first aspect as such or any preceding implementation form of the first aspect, the asymmetric rise and fall times create overlapping low periods in the differential output signals during input signal transitions.

In a fourth implementation form of the system, according to the first aspect as such or any preceding implementation form of the first aspect, the timer circuit comprises a NOR gate configured to receive the differential output signals; a pulse stretcher comprising a buffer circuit and an OR gate configured to generate the reset signal; a first p-channel transistor and a first n-channel transistor configured as a discharge path; a first capacitor coupled between the discharge path and ground; a charging network coupled to the first p-channel transistor; and a comparator, inverter, or a buffer circuit configured to generate the fault signal in response to a voltage across the first capacitor exceeding a threshold voltage.

In a fifth implementation form of the system, according to the first aspect as such or any preceding implementation form of the first aspect, the charging network comprises one of a current source configured to generate a charging current that creates a linear voltage increase across the first capacitor with a slope equal to the charging current divided by a capacitance of the first capacitor; or a resistor configured to create an exponential voltage increase across the first capacitor with a time constant equal to a resistance of the resistor multiplied by the capacitance of the first capacitor.

In a sixth implementation form of the system, according to the first aspect as such or any preceding implementation form of the first aspect, the fault signal indicates that a frequency of transitions in the differential input signals has dropped below a predetermined threshold; or the differential input signals have stopped transitioning.

A second aspect relates to a circuit, comprising a detector and stretcher circuit configured to receive differential input signals, and generate differential output signals having asymmetric rise and fall times; and a timer circuit coupled to the detector and stretcher circuit and configured to monitor the differential output signals, generate a reset signal in response to the differential output signals being in a low state, and generate a fault signal in response to a time between reset signals exceeding a threshold.

In a first implementation form of the detector and stretcher circuit, according to the second aspect as such, the detector and stretcher circuit comprises a differential pair of transistors having base terminals configured to receive the differential input signals; a first current source and a second current source configured to generate pull-up currents; a third current source configured to generate a pull-down current; a first clamping network and a second clamping network coupled to collector terminals of the differential pair of transistors; and a first capacitor and a second capacitor coupled between the collector terminals and ground.

In a second implementation form of the detector and stretcher circuit, according to the second aspect as such or any preceding implementation form of the second aspect, the first clamping network and the second clamping network are configured to limit a minimum voltage at the collector terminals of the differential pair of transistors to approximately N number of base-emitter voltage drops below the supply voltage, where N is an integer greater than two corresponding to the low voltage rail requirement of subsequent logic circuits in the system.

In a third implementation form of the detector and stretcher circuit, according to the second aspect as such or any preceding implementation form of the second aspect, the asymmetric rise and fall times create overlapping low periods in the differential output signals during input signal transitions.

In a fourth implementation form of the detector and stretcher circuit, according to the second aspect as such or any preceding implementation form of the second aspect, the timer circuit comprises a NOR gate configured to receive the differential output signals; a pulse stretcher comprising a buffer circuit and an OR gate configured to generate the reset signal; a first p-channel transistor and a first n-channel transistor configured as a discharge path; a first capacitor coupled between the discharge path and ground; a charging network coupled to the first p-channel transistor; and a comparator, inverter, or buffer circuit configured to generate the fault signal in response to a voltage across the first capacitor exceeding a threshold voltage.

In a fifth implementation form of the detector and stretcher circuit, according to the second aspect as such or any preceding implementation form of the second aspect, the charging network comprises one of a current source configured to generate a charging current that creates a linear voltage increase across the first capacitor with a slope equal to the charging current divided by a capacitance of the first capacitor; or a resistor configured to create an exponential voltage increase across the first capacitor with a time constant equal to a resistance of the resistor multiplied by the capacitance of the first capacitor.

In a sixth implementation form of the detector and stretcher circuit, according to the second aspect as such or any preceding implementation form of the second aspect, the fault signal indicates that a frequency of transitions in the differential input signals has dropped below a predetermined threshold; or the differential input signals have stopped transitioning.

A third aspect relates to a method, comprising receiving differential input signals; generating differential output signals having asymmetric rise and fall times based on the differential input signals; monitoring the differential output signals; generating a reset signal in response to the differential output signals being in a low state; and generating a fault signal in response to a time between reset signals exceeding a threshold.

In a first implementation form of the method, according to the third aspect as such, generating the differential output signals comprises receiving the differential input signals at base terminals of a differential pair of transistors; generating pull-up currents using a first current source and a second current source; generating a pull-down current using a third current source; clamping collector terminals of the differential pair of transistors using a first clamping network and a second clamping network; and coupling a first capacitor and a second capacitor between the collector terminals and ground.

In a second implementation form of the method, according to the third aspect as such or any preceding implementation form of the third aspect, clamping the collector terminals comprises limiting a minimum voltage at the collector terminals to approximately N number of base-emitter voltage drops below a supply voltage, where N is an integer greater than two corresponding to the low voltage rail requirement of subsequent logic circuits in the system.

In a third implementation form of the method, according to the third aspect as such or any preceding implementation form of the third aspect, generating the reset signal comprises receiving the differential output signals at a NOR gate; generating a stretched pulse using a buffer circuit and an OR gate; discharging a first capacitor through a first p-channel transistor and a first n-channel transistor in response to the stretched pulse; and charging the first capacitor through a charging network when the reset signal is inactive.

In a fourth implementation form of the method, according to the third aspect as such or any preceding implementation form of the third aspect, charging the first capacitor comprises one of generating a linear voltage increase across the first capacitor using a current source; or generating an exponential voltage increase across the first capacitor using a resistor.

In a fifth implementation form of the method, according to the third aspect as such or any preceding implementation form of the third aspect, generating the fault signal comprises indicating that a frequency of transitions in the differential input signals has dropped below a predetermined threshold; or the differential input signals have stopped transitioning.

Although the description has been described in detail, it should be understood that various changes, substitutions, and alterations may be made without departing from the spirit and scope of this disclosure as defined by the appended claims. The same elements are designated with the same reference numbers in the various figures. Moreover, the scope of the disclosure is not intended to be limited to the particular embodiments described herein, as one of ordinary skill in the art will readily appreciate from this disclosure that processes, machines, manufacture, compositions of matter, means, methods, or steps, presently existing or later to be developed, may perform substantially the same function or achieve substantially the same result as the corresponding embodiments described herein. Accordingly, the appended claims are intended to include within their scope such processes, machines, manufacture, compositions of matter, means, methods, or steps.

The specification and drawings are, accordingly, to be regarded simply as an illustration of the disclosure as defined by the appended claims, and are contemplated to cover any and all modifications, variations, combinations, or equivalents that fall within the scope of the present disclosure.

What is claimed is:

1. A system, comprising:
a writer circuit configured to:
receive differential input signals from a System on Chip (SoC), and
generate write currents through a magnetic recording head based on the differential input signals; and
a fault detection circuit comprising:
a detector and stretcher circuit configured to:
monitor the differential input signals received by the writer circuit; and
generate differential output signals having asymmetric rise and fall times, and
a timer circuit coupled to the detector and stretcher circuit and configured to:
monitor the differential output signals;
generate a reset signal in response to the differential output signals being in a low state; and
generate a fault signal in response to a time between reset signals exceeding a threshold.

2. The system of claim 1, wherein the detector and stretcher circuit comprises:
a differential pair of transistors having base terminals configured to receive the differential input signals;
a first current source and a second current source configured to generate pull-up currents;
a third current source configured to generate a pull-down current;
a first clamping network and a second clamping network coupled to collector terminals of the differential pair of transistors; and
a first capacitor and a second capacitor coupled between the collector terminals and ground.

3. The system of claim 2, wherein the first clamping network and the second clamping network are configured to limit a minimum voltage at the collector terminals of the differential pair of transistors to approximately N number of base-emitter voltage drops below the supply voltage, where N is an integer greater than two corresponding to the low voltage rail requirement of subsequent logic circuits in the system.

4. The system of claim 2, wherein the asymmetric rise and fall times create overlapping low periods in the differential output signals during input signal transitions.

5. The system of claim 1, wherein the timer circuit comprises:
a NOR gate configured to receive the differential output signals;
a pulse stretcher comprising a buffer circuit and an OR gate configured to generate the reset signal;
a first p-channel transistor and a first n-channel transistor configured as a discharge path;
a first capacitor coupled between the discharge path and ground;
a charging network coupled to the first p-channel transistor; and
a comparator, inverter, or a buffer circuit configured to generate the fault signal in response to a voltage across the first capacitor exceeding a threshold voltage.

6. The system of claim 5, wherein the charging network comprises one of:
a current source configured to generate a charging current that creates a linear voltage increase across the first capacitor with a slope equal to the charging current divided by a capacitance of the first capacitor; or
a resistor configured to create an exponential voltage increase across the first capacitor with a time constant equal to a resistance of the resistor multiplied by the capacitance of the first capacitor.

7. The system of claim 1, wherein the fault signal indicates that:
a frequency of transitions in the differential input signals has dropped below a predetermined threshold; or
the differential input signals have stopped transitioning.

8. A circuit, comprising:
a detector and stretcher circuit configured to:
receive differential input signals, and
generate differential output signals having asymmetric rise and fall times; and
a timer circuit coupled to the detector and stretcher circuit and configured to:
monitor the differential output signals,
generate a reset signal in response to the differential output signals being in a low state, and
generate a fault signal in response to a time between reset signals exceeding a threshold.

9. The circuit of claim 8, wherein the detector and stretcher circuit comprises:
a differential pair of transistors having base terminals configured to receive the differential input signals;
a first current source and a second current source configured to generate pull-up currents;
a third current source configured to generate a pull-down current;
a first clamping network and a second clamping network coupled to collector terminals of the differential pair of transistors; and
a first capacitor and a second capacitor coupled between the collector terminals and ground.

10. The circuit of claim 9, wherein the first clamping network and the second clamping network are configured to limit a minimum voltage at the collector terminals of the differential pair of transistors to approximately N number of base-emitter voltage drops below the supply voltage, where N is an integer greater than two corresponding to the low voltage rail requirement of subsequent logic circuits in the system.

11. The circuit of claim 9, wherein the asymmetric rise and fall times create overlapping low periods in the differential output signals during input signal transitions.

12. The circuit of claim 8, wherein the timer circuit comprises:
a NOR gate configured to receive the differential output signals;
a pulse stretcher comprising a buffer circuit and an OR gate configured to generate the reset signal;
a first p-channel transistor and a first n-channel transistor configured as a discharge path;
a first capacitor coupled between the discharge path and ground;
a charging network coupled to the first p-channel transistor; and
a comparator, inverter, or buffer circuit configured to generate the fault signal in response to a voltage across the first capacitor exceeding a threshold voltage.

13. The circuit of claim 12, wherein the charging network comprises one of:
a current source configured to generate a charging current that creates a linear voltage increase across the first capacitor with a slope equal to the charging current divided by a capacitance of the first capacitor; or
a resistor configured to create an exponential voltage increase across the first capacitor with a time constant equal to a resistance of the resistor multiplied by the capacitance of the first capacitor.

14. The circuit of claim 8, wherein the fault signal indicates that:
a frequency of transitions in the differential input signals has dropped below a predetermined threshold; or
the differential input signals have stopped transitioning.

15. A method, comprising:
receiving differential input signals;
generating differential output signals having asymmetric rise and fall times based on the differential input signals;
monitoring the differential output signals;
generating a reset signal in response to the differential output signals being in a low state; and
generating a fault signal in response to a time between reset signals exceeding a threshold.

16. The method of claim 15, wherein generating the differential output signals comprises:
receiving the differential input signals at base terminals of a differential pair of transistors;
generating pull-up currents using a first current source and a second current source;
generating a pull-down current using a third current source;
clamping collector terminals of the differential pair of transistors using a first clamping network and a second clamping network; and
coupling a first capacitor and a second capacitor between the collector terminals and ground.

17. The method of claim 16, wherein clamping the collector terminals comprises limiting a minimum voltage at the collector terminals to approximately N number of base-emitter voltage drops below a supply voltage, where N is an integer greater than two corresponding to the low voltage rail requirement of subsequent logic circuits in the system.

18. The method of claim 15, wherein generating the reset signal comprises:
receiving the differential output signals at a NOR gate;
generating a stretched pulse using a buffer circuit and an OR gate;
discharging a first capacitor through a first p-channel transistor and a first n-channel transistor in response to the stretched pulse; and
charging the first capacitor through a charging network when the reset signal is inactive.

19. The method of claim 18, wherein charging the first capacitor comprises one of:
generating a linear voltage increase across the first capacitor using a current source; or
generating an exponential voltage increase across the first capacitor using a resistor.

20. The method of claim 15, wherein generating the fault signal comprises indicating that:
a frequency of transitions in the differential input signals has dropped below a predetermined threshold; or
the differential input signals have stopped transitioning.
